(19) United States
(12) Patent Application Publication
(10) Pub. No.: US 2025/0287514 A1
(43) Pub. Date: Sep. 11, 2025

(54) METHOD FOR MANUFACTURING ELECTRONIC COMPONENT DEVICE

(71) Applicant: Resonac Corporation, Minato-ku, Tokyo (JP)

(72) Inventors: Yuki IMAZU, Minato-ku, Tokyo (JP); Keiichi HATAKEYAMA, Minato-ku, Tokyo (JP); Motoo AOYAMA, Minato-ku, Tokyo (JP); Dongchul KANG, Minato-ku, Tokyo (JP); Sadaaki KATO, Minato-ku, Tokyo (JP); Keiko UENO, Minato-ku, Tokyo (JP); Kazue HIRANO, Minato-ku, Tokyo (JP); Hiroaki MATSUBARA, Minato-ku, Tokyo (JP); Kei ITAGAKI, Minato-ku, Tokyo (JP); Masaya TOBA, Minato-ku, Tokyo (JP)

(21) Appl. No.: 18/859,545

(22) PCT Filed: Sep. 2, 2022
(86) PCT No.: PCT/JP2022/033144

§ 371 Date: Oct. 24, 2024

(51) Int. Cl. H05K 3/46; H05K 3/00; H05K 3/30

(52) U.S. Cl. CPC H05K 3/467; H05K 3/0044; H05K 3/303; H05K 2203/0228; H05K 2203/107

(57) ABSTRACT

A method for manufacturing an electronic device, which includes, preparing an intermediate structure including a base material and a wiring layer, the base material having a first main surface and a second main surface on a rear side of the first main surface, the wiring layer being provided on the first main surface and having an insulating resin layer and wiring, the base material having a resin portion including a through portion penetrating from the first main surface to the second main surface, the wiring layer forming a trench having a bottom surface on which the through portion is exposed; and cutting the through portion along the trench, thereby forming a plurality of wiring structures, each having the divided base material.

### TECHNICAL FIELD

The present disclosure relates to a method for manufacturing an electronic component device.

### BACKGROUND ART

An exemplary semiconductor package with a plurality of semiconductor components arranged two-dimensionally is a so-called 2.3-dimensional type, which features an interposer with fine wiring for connecting the multiple semiconductor components (e.g., Patent Literatures 1 and 2).

### CITATION LIST

### Patent Literature

Patent Literature 1: U.S. Patent Application Publication No. 2021/0074646.

Patent Literature 2: U.S. Patent Application Publication No. 2021/0074645.

### SUMMARY OF INVENTION

### Technical Problem

In a method for manufacturing an electronic component device that has an insulating resin layer and a wiring layer including wiring, multiple wiring structures may be formed from a single intermediate structure on which a wiring layer is formed by cutting a base material, which includes a resin portion, along with the wiring layer. However, since it is typical that the insulating resin layer constituting the wiring layer and the resin portion constituting the base material have different physical properties like hardness, cutting both at the same time using the same method is likely to cause a defect such as damage to one of them. This is particularly challenging when the base material includes a relatively hard resin portion that contains a lot of inorganic filler, as a cutting method suitable for cutting the resin portion is liable to cause delamination or damage to the insulating resin layer that constitutes the wiring layer.

### Solution to Problem

The present disclosure includes the following items.

[1] A method for manufacturing an electronic component device, comprising:

preparing an intermediate structure comprising a base material and a wiring layer, the base material having a first main surface and a second main surface on a rear side of the first main surface, the wiring layer being provided on the first main surface and comprising an insulating resin layer and wiring provided in the insulating resin layer, the base material comprising a resin portion comprising a through portion penetrating from the first main surface to the second main surface, the wiring layer forming a trench having a bottom surface on which the through portion is exposed; and

cutting the through portion along the trench, thereby forming a plurality of wiring structures, each comprising the divided base material and the wiring layer provided on the base material.

[2] The method according to [1], in which

the resin portion comprises an inorganic filler,

the insulating resin layer does not comprise an inorganic filler, or the insulating resin layer comprises the inorganic filler, and

in a case where the insulating resin layer comprises the inorganic filler, a ratio of a volume of the inorganic filler comprised in the insulating resin layer to a volume of the insulating resin layer is smaller than a ratio of a volume of the inorganic filler comprised in the resin portion to a volume of the resin layer.

[3] The method according to [1], in which the intermediate structure is prepared in a way that includes forming the wiring layer forming the trench on the base material.

[4] The method according to [1], in which the intermediate structure is prepared in a way that includes forming the wiring layer forming the trench on a carrier substrate, and shifting the wiring layer from the carrier substrate onto the base material.

[5] The method according to any one of [1] to [4], in which

the wiring layer is

formed in a way that includes repeating forming a pattern layer through exposure and development of a photosensitive resin layer and forming a conductor layer, the pattern layer having a pattern including an opening for the wiring and an opening for the trench, the conductor layer comprising a via portion that fills the opening for the wiring, and

the insulating resin layer is formed by a plurality of the pattern layers, the wiring is formed by a plurality of the conductor layers, and the trench is formed by connecting a plurality of the openings for the trench formed by a plurality of the pattern layers.

[6] The method according to any one of [1] to [4], in which

the wiring layer is

formed in a way that includes repeating removing a part of a resin layer with laser irradiation to form a pattern layer and forming a conductor layer, the pattern layer having a pattern including an opening for the wiring and an opening for the trench, the conductor layer comprising a via portion that fills the opening for the wiring, and

the insulating resin layer is formed by a plurality of the pattern layers, the wiring is formed by a plurality of the conductor layers, and the trench is formed by connecting a plurality of the openings for the trench formed by a plurality of the pattern layers.

[7] The method according to any one of [1] to [4], in which

the wiring layer is

formed in a way that includes repeating forming a pattern layer through exposure and development of a photosensitive resin layer and forming a conductor layer, the pattern layer having a pattern including an opening for the wiring, the conductor layer comprising a via portion that fills the opening for the wiring, and

the insulating resin layer is formed by a plurality of the pattern layers, the wiring is formed by a plurality of the conductor layers, and a part of the formed insulating resin layer is removed with laser irradiation to form the trench.

[8] The method according to any one of [1] to [7], further comprising mounting a plurality of semiconductor components on the wiring layer,

in which each of the plurality of wiring structures being formed has one or more of the semiconductor components.

[9] The method according to any one of [1] to [7], in which

the base material further comprises an internal wiring layer exposed on the second main surface,

the internal wiring layer forms an internal trench filled with the through portion of the resin portion,

the method further comprises mounting a plurality of semiconductor components on the internal wiring layer,

the through portion is cut along the trench and the internal trench, and

each of the plurality of wiring structures being formed comprises one or more of the semiconductor components.

[10] The method according to [8] or [9], in which

the base material further comprises a relay wiring portion comprising relay wiring electrically connected to the plurality of semiconductor components, the relay wiring portion being sealed by the resin portion, and

each of the plurality of wiring structures being formed comprises the relay wiring portion and two or more of the semiconductor components electrically connected via the relay wiring portion.

[11] The method according to any one of [1] to [10], in which the width of the trench increases in a direction away from the base material.

[ ] The method according to any one of [1] to [11], further comprising mounting the wiring structure on an organic wiring substrate.

### Advantageous Effects of Invention

A method is disclosed for easily manufacturing a wiring structure including a base material that has a resin portion containing a lot of inorganic fillers and a wiring layer provided on the base material. This method is applicable, for example, to the fabrication of 2.3-dimensional semiconductor packages.

### BRIEF DESCRIPTION OF DRAWINGS

FIG. 1 is a process diagram illustrating an example of a method for manufacturing an electronic component device.

FIG. 2 is a process diagram illustrating an example of a method for manufacturing an electronic component device.

FIG. 3 is a process diagram illustrating an example of a method for manufacturing an electronic component device.

FIG. 4 is a process diagram illustrating an example of a method for manufacturing an electronic component device.

FIG. 5 is a process diagram illustrating an example of a method for manufacturing an electronic component device having a semiconductor component.

FIG. 6 is a process diagram illustrating an example of a method for manufacturing an electronic component device having a semiconductor component.

FIG. 7 is a process diagram illustrating an example of a method for manufacturing an electronic component device having a semiconductor component.

FIG. 8 is a process diagram illustrating an example of a method for manufacturing an electronic component device having a semiconductor component.

FIG. 9 is a process diagram illustrating an example of a method for manufacturing an electronic component device having a semiconductor component.

FIG. 10 is a process diagram illustrating an example of a method for manufacturing an electronic component device having a semiconductor component.

FIG. 11 is a process diagram illustrating an example of a method for manufacturing an electronic component device having a semiconductor component.

### DESCRIPTION OF EMBODIMENTS

The present disclosure is not limited to the following examples. In the following examples, duplicated descriptions may be omitted.

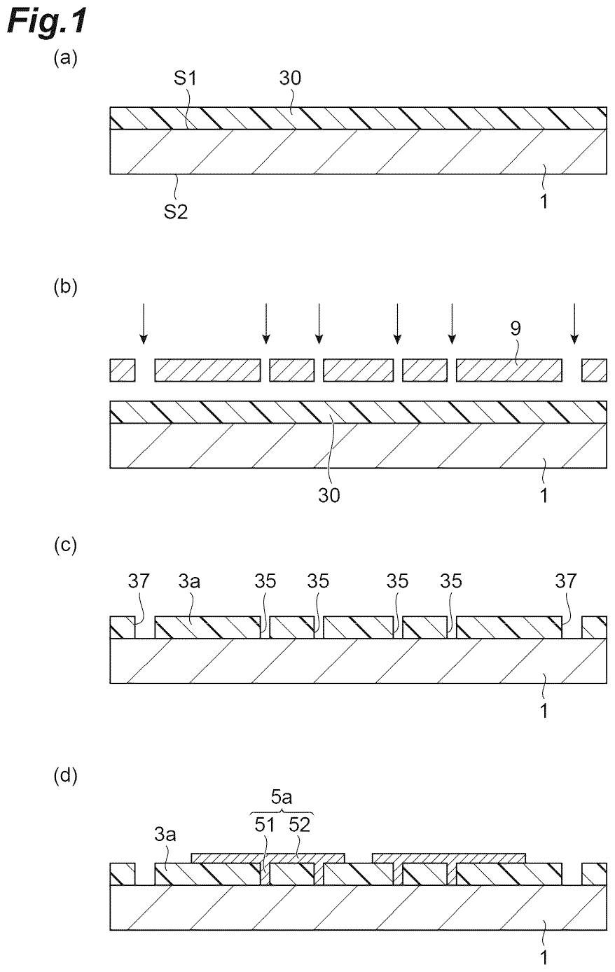

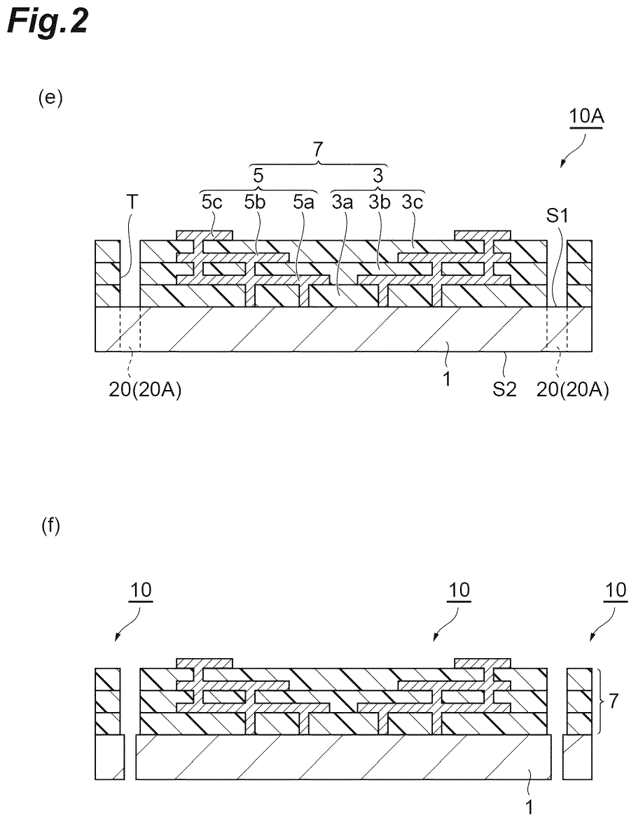

FIGS. 1 and 2 are process diagrams illustrating an example of a method for manufacturing an electronic component device. The method illustrated in FIG. 1 and FIG. 2 includes preparing an intermediate structure 10A having a base material 1 and a wiring layer 7. The base material 1 has a first main surface S1 and a second main surface S2 on the rear side of the first main surface S1. The wiring layer 7 is provided on the first main surface S1 and has an insulating resin layer 3 and wiring 5 provided in the insulating resin layer 3. The base material 1 has a resin portion 20 including a through portion 20A penetrating from the first main surface S1 to the second main surface S2. The insulating resin layer 3 forms a trench T having a bottom surface that exposes the through portion 20A. The method also includes cutting the through portion 20A along the trench T to form a plurality of wiring structures 10, each having the base material 1 divided and the wiring layer 7 provided on the base material 1.

The through portion 20A is a portion of the resin portion 20 that penetrates from the first main surface SI to the second main surface S2. The resin portion 20 includes at least the through portion 20A and can be a member integrally formed from a resin material such as a sealing material. The entire first main surface S1 of the base material 1 may also be the surface of the resin portion 20. Alternatively, a relay wiring portion, which will be described later, may be provided in the base material 1 separately from the resin portion 20 including the through portion 20A, and the relay wiring portion may be exposed on the first main surface S1.

The resin portion 20 includes a resin and an inorganic filler. The insulating resin layer 3 may contain a resin and an inorganic filler. In the case where the insulating resin layer 3 contains an inorganic filler, the ratio of the volume of the inorganic filler contained in the insulating resin layer 3 to the volume of the insulating resin layer 3 is smaller than the ratio of the volume of the inorganic filler contained in the resin portion 20 to the volume of the resin portion 20. Due to the difference in the ratio of inorganic fillers, the resin portion 20 is relatively harder. Different hardnesses often result in different suitable cutting conditions, but according to the method disclosed herein, since only the resin portion 20 (the through portion 20A) is cut, it is possible to employ cutting conditions suitable for cutting the resin portion 20 while avoiding any influence on the insulating resin layer 3. The resin portion 20 (the through portion 20A) is cut, for example, by a rotating blade.

The ratio of the volume of the inorganic filler in the resin portion 20 to the volume of the resin portion 20 may be, for example, 10% or more and 95% or less by volume. The ratio of the volume of the inorganic filler in the insulating resin layer 3 to the volume of the insulating resin layer 3 may be, for example, 0% or more and 50% or less by volume.

In the example of FIGS. 1 and 2, the wiring layer 7 is formed by repeatedly forming a pattern layer 3a having a pattern including an opening for the wiring 35 and an opening for the trench 37 by exposing and developing a photosensitive resin layer 30 formed on the first main surface S1 of the base material 1, and forming a conductor layer 5a including a via portion 51 filling the opening for the wiring 35 and a wiring pattern portion 52 provided on the pattern layer 3a. The insulating resin layer 3 is formed by the first pattern layer 3a, a second pattern layer 3b, and a third pattern layer 3c, which are formed in sequence from the side of the base material 1. The wiring 5 is formed by the first conductor layer 5a, a second conductor layer 5b, and a third conductor layer 5c, which are formed in sequence from the side of the base material 1. The trench T penetrating the insulating resin layer 3 is formed by connecting the multiple openings for the trench 37 formed by the plurality of pattern layers 3a, 3b, and 3c.

The photosensitive resin layer 30 and the pattern layers 3a, 3b, and 3c can be formed using conventional resist materials that are used to form an insulating resin layer of a wiring layer. For the exposure of the resin layer 30, active light rays such as ultraviolet light are applied through a mask 9, which has an opening provided at a position corresponding to the opening for the wiring 35 and the opening for the trench 37. Instead of using the exposure and development method, a part of the resin layer 30 may be removed with laser irradiation to form the pattern layers 3a, 3b, and 3c, which have a pattern including the opening for the wiring 35 and the opening for the trench 37. In this case, the resin layer 30 may be non-photosensitive.

The conductor layers 5a, 5b, and 5c and the wiring 5 can be formed using conventional methods such as plating, printing of conductor paste, or sputtering.

The wiring layer 7 is used, for example, as a redistribution layer connected to a semiconductor component including an IC chip. The number of pattern layers and conductor layers that constitute the wiring layer 7 is not limited to a particular number, but may be, for example, 2 or more and 8 or less, respectively. The thickness of the entire wiring layer 7 may be, for example, 10 μm or more and 150 μm or less.

The intermediate structure 10A may be prepared by a method that includes forming the wiring layer 7, which forms the trench 1, on a carrier substrate separate from the base material 1, and shifting the wiring layer 7 from the carrier substrate onto the base material 1.

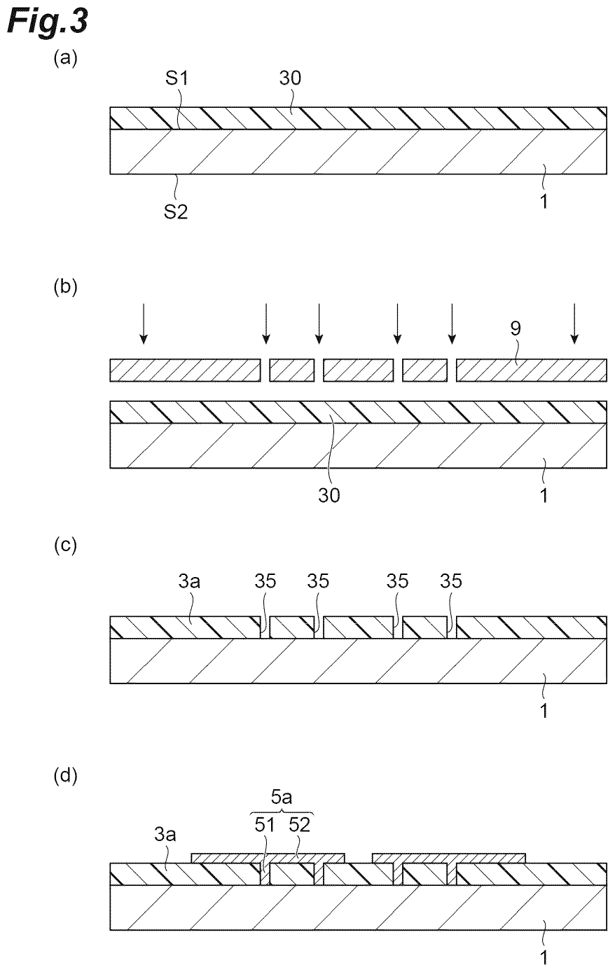

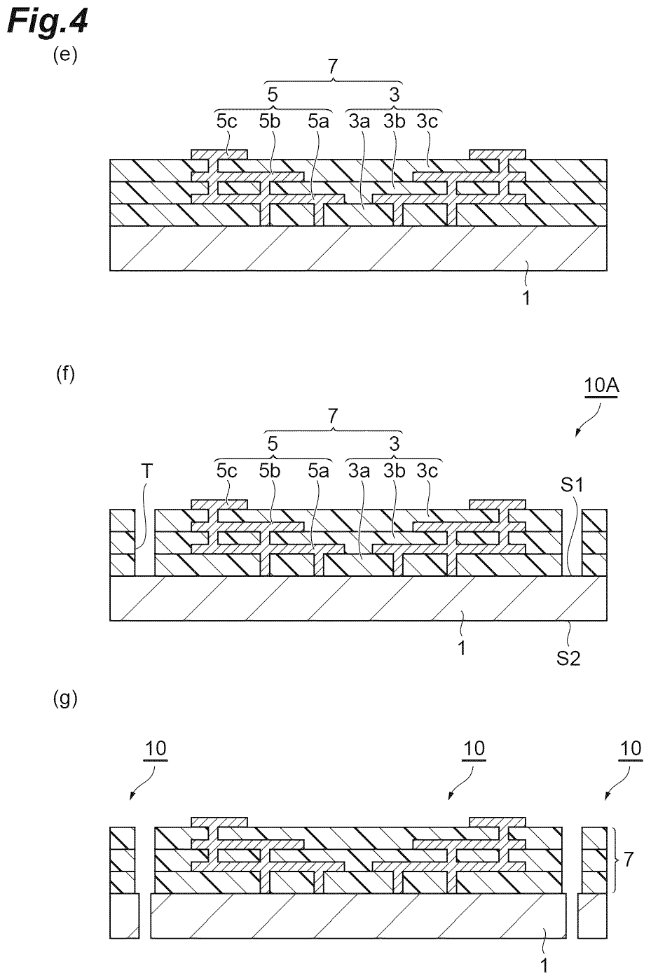

FIGS. 3 and 4 are process diagrams illustrating another exemplary method for manufacturing an electronic component device. In the case of the method illustrated in FIGS. 3 and 4, the wiring layer 7 is formed in a way, which includes repeatedly forming a pattern layer 3a having a pattern including an opening for the wiring 35 by exposure and development of the photosensitive resin layer 30 and forming a conductor layer 5a including a via portion 51 that fills the opening for the wiring 35 and a wiring pattern portion 52 provided on the pattern layer 3a. As in the method for FIGS. 1 and 2, the insulating resin layer 3 is formed by the plurality of pattern layers 3a, 3b, and 3c, and the wiring 5 is formed by the plurality of conductor layers 5a, 5b, and 5c. Then, as illustrated in FIG. 4(f), a part of the formed insulating resin layer 3 is removed with laser irradiation to form the trench T.

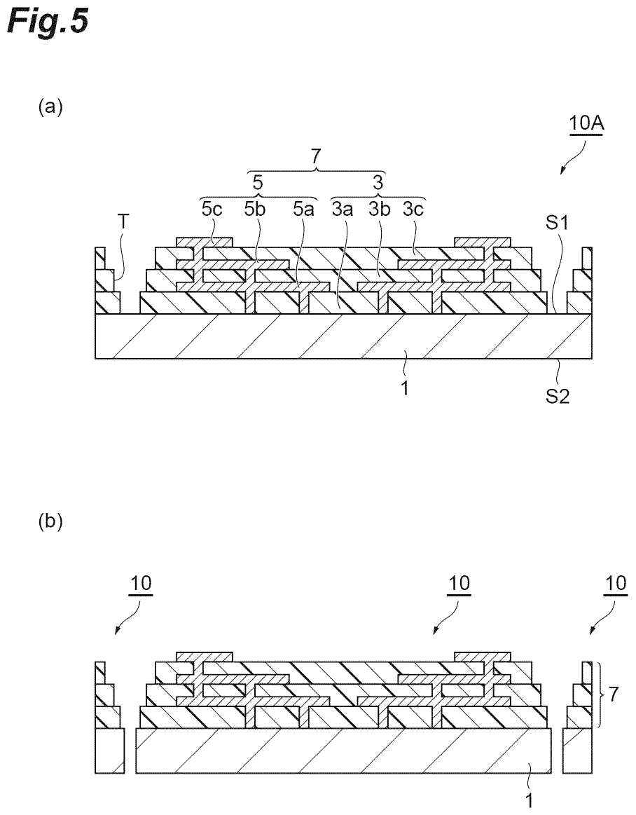

As illustrated in another example in FIG. 5, the trench T may be formed with a width that widens in the direction away from the base material 1. By varying the width of the opening for the trench formed by the multiple pattern layers 3a, 3b, and 3c, it is possible to form the trench T with a gradually widening width. In the case where the end face of the trench T (insulating resin layer 3) is inclined in this way, the occurrence of cracks or delamination starting from the edge of the insulating resin layer 3 can be suppressed.

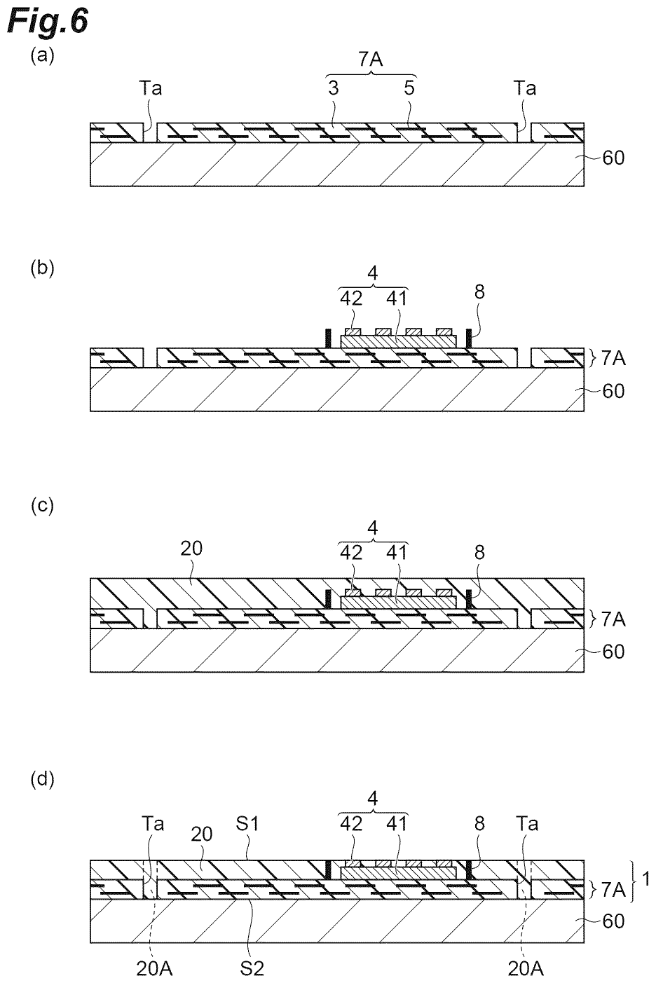

FIGS. 6, 7, 8, and 9 are process diagrams illustrating an example of a method for manufacturing an electronic component device having multiple semiconductor components. In the method illustrated in FIGS. 6 to 9, as illustrated in FIG. 6, the base material 1 is formed in a way that includes forming an internal wiring layer 7A forming an internal trench Ta, arranging a relay wiring portion 4 and a copper pillar 8 on the internal wiring layer 7A, forming the resin portion 20 that seals the relay wiring portion 4, and removing the surface layer portion of the resin portion 20 opposite the internal wiring layer 7A to form a flat surface that exposes the relay wiring portion 4 and the copper pillar 8. The base material 1 being formed includes the internal wiring layer 7A, the relay wiring portion 4, and the resin portion 20. The resin portion 20 includes a portion that fills the internal trench Ta of the internal wiring layer 7A and includes a through portion 20A that penetrates from the first main surface S1 to the second main surface S2 on the rear side. The internal wiring layer 7A is exposed on the second main surface S2 of the base material 1. The internal wiring layer 7A can be formed by exposure and development of a photosensitive resin layer, laser irradiation, or a combination of these, similar to the method illustrated in FIGS. 1 to 4.

The relay wiring portion 4 has a main body 41 including relay wiring electrically connected to a plurality of semiconductor components and has a terminal 42 provided on the outer surface of the main body 41. The relay wiring portion 4 is arranged on the internal wiring layer 7A in the orientation in which the terminal 42 is positioned on the side opposite the internal wiring layer 7A. The relay wiring portion 4 may be a silicon interposer including a silicon substrate. The copper pillar 8 can be formed using conventional by conventional methods such as plating or printing of a conductive paste. The copper pillar 8 is electrically connected to the wiring 5 in the internal wiring layer 7A.

The resin portion 20 can be formed using conventional sealing materials such as a thermosetting resin composition containing an inorganic filler. The inorganic filler may include, for example, silica particles.

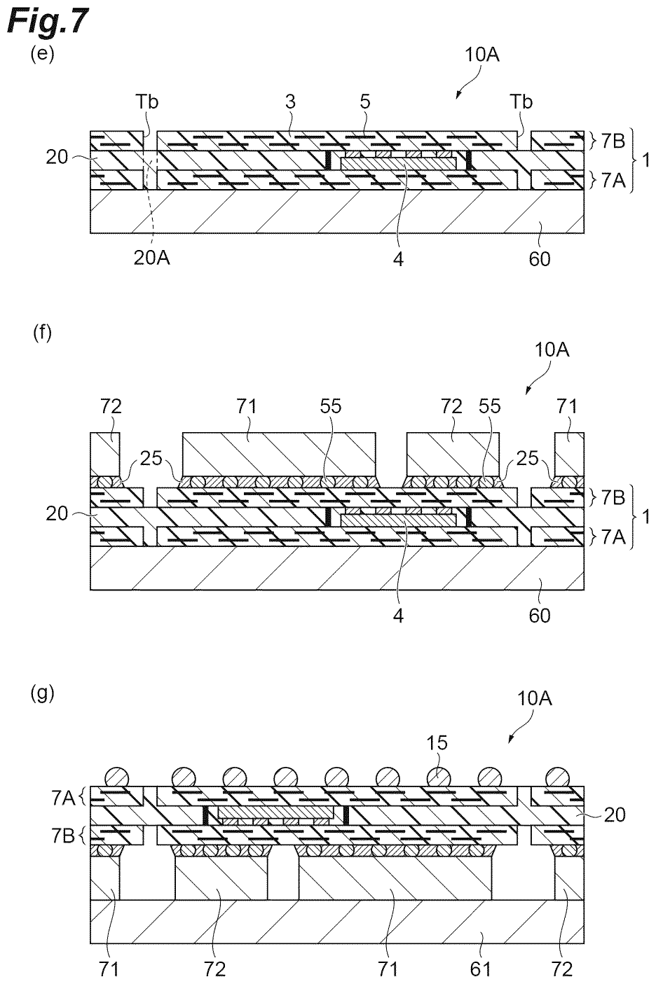

Subsequently, as illustrated in FIG. 7(e), a wiring layer 7B is formed on the first main surface SI of the base material 1, forming a trench Tb having a bottom surface that exposes the through portion 20A. The trench Tb is formed at a position overlapping with the internal trench Ta. The wiring layer 7B can be formed using a method similar to that illustrated in FIGS. 1 to 4. The wiring 5 in the wiring layer 7B is electrically connected to the relay wiring portion 4 and the copper pillar 8.

On the formed wiring layer 7B, a plurality of semiconductor components 71 and 72 are mounted (FIG. 7(f)). The semiconductor components 71 and 72 each have a bump 55, and the semiconductor components 71 and 72 are electrically connected to the wiring layer 7B via the bump 55. The space between the semiconductor components 71 and 72 and the wiring layer 7B is filled with an underfill material 25.

The intermediate structure 10A having the base material 1, the wiring layer 7B, and the semiconductor components 71 and 72 is shifted onto a carrier substrate 61, which is separate from the carrier substrate 60, in the orientation in which the semiconductor components 71 and 72 are positioned on the side of the carrier substrate 61, and in this state, a bump 15 is provided on the internal wiring layer 7A (FIG. 7(g)).

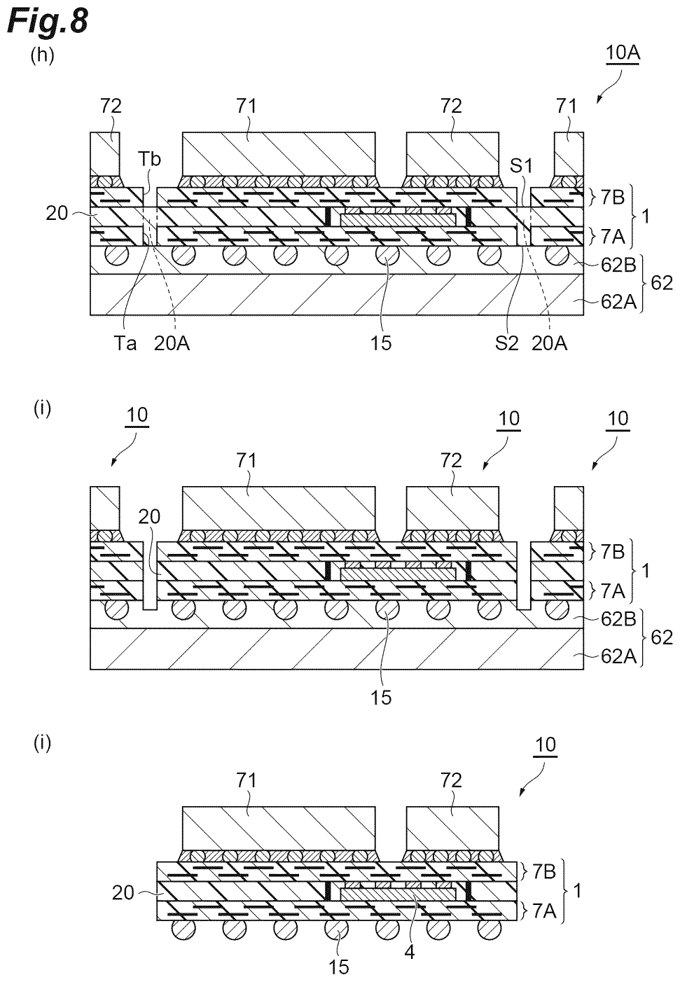

Then, as illustrated in FIG. 8(a), the intermediate structure 10A is shifted onto another carrier substrate 62. The carrier substrate 62 has a support substrate 62A and a temporary fixing material layer 62B provided on the support substrate 62A. The intermediate structure 10A is temporarily fixed to the carrier substrate 62 in the orientation in which the bump 15 contacts the temporary fixing material layer 62B. In this state, the through portion 20A of the resin portion 20 is cut from the side of the trench Tb along the trench Tb and the internal trench Ta, and thus a plurality of wiring structures 10 is formed on the carrier substrate 62 (FIG. 8(i)).

The wiring structure 10 is delaminated from the carrier substrate 62 (FIG. 8(j)). The wiring structure 10 is an electronic component device having the relay wiring portion 4 and the plurality of semiconductor components 71 and 72, that is, a semiconductor package. The plurality of semiconductor components 71 and 72 are electrically connected through the relay wiring portion 4. The semiconductor components 71 and 72 constituting one wiring structure 10 can be components having different functions. For example, the semiconductor component 71 may be a system-on-chip (SoC), and the semiconductor component 72 may be a memory. A single wiring structure 10 (semiconductor package) may also have a plurality of semiconductor components of the same type.

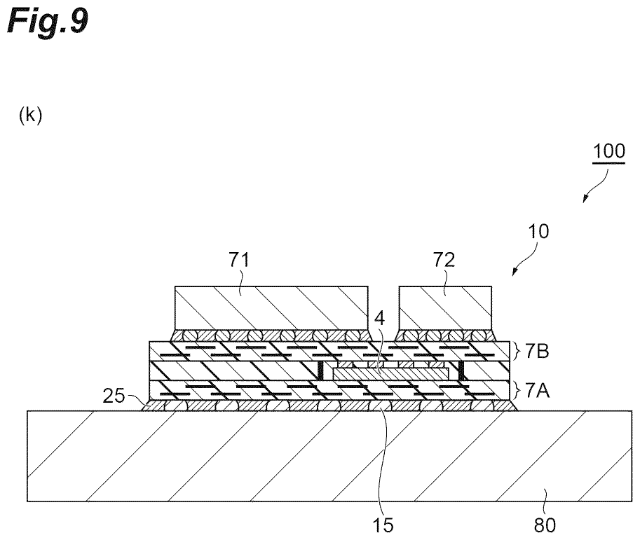

As illustrated in FIG. 9, the wiring structure 10 is mounted on an organic wiring substrate 80 to obtain an electronic component device 100. The wiring structure 10 is electrically connected to the organic wiring substrate 80 via the bump 15. The underfill material 25 may be filled between the wiring structure 10 and the organic wiring substrate 80. Various electronic components other than the wiring structure 10 may be mounted on one organic wiring substrate 80.

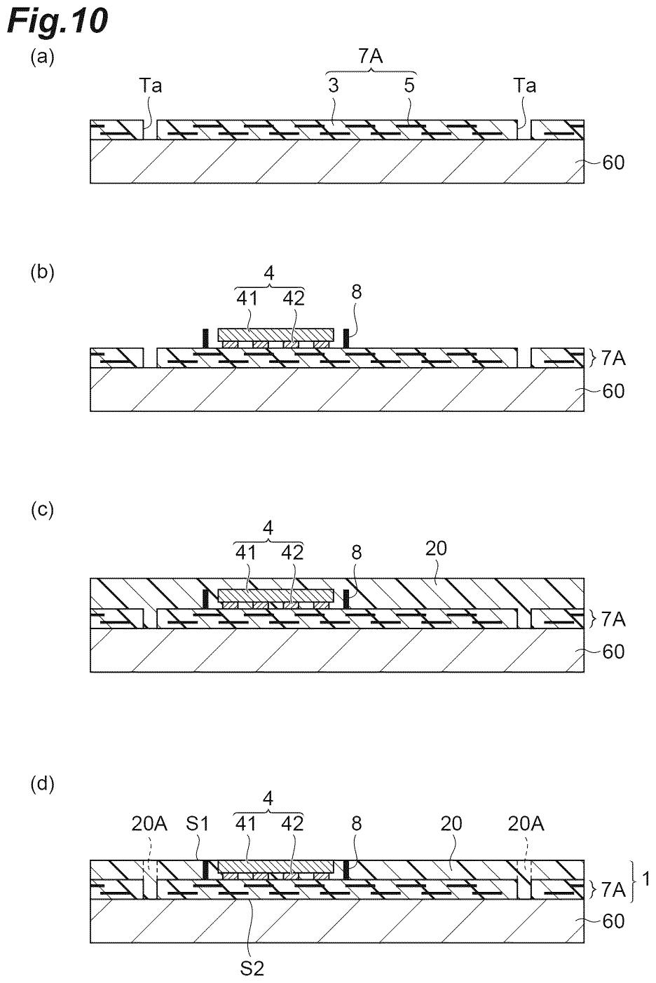

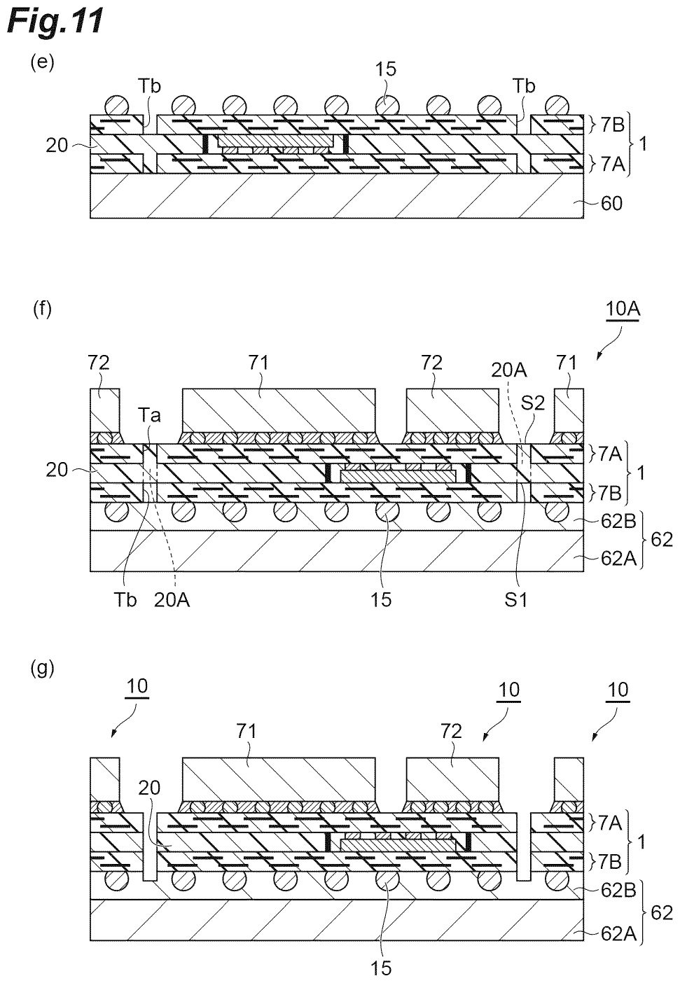

FIGS. 10 and 11 are process diagrams illustrating another example of a method for manufacturing an electronic component device having multiple semiconductor components. The method illustrated in FIGS. 10 and 11 differs from the methods illustrated in FIGS. 7 to 9 in that the relay wiring portion 4 is arranged on the internal wiring layer 7A in the orientation in which the terminal 42 is positioned on the side of the internal wiring layer 7A (FIG. 10(b)), and in that multiple semiconductor components 71 and 72 are mounted on the internal wiring layer 7A (FIG. 11(f)). The bump 15 is provided on the wiring layer 7B with the intermediate structure 10A temporarily fixed to the carrier substrate 60 (FIG. 11(e)).

As illustrated in FIGS. 11(f) and 11(g), while the intermediate structure 10A is temporarily fixed to the carrier substrate 62, the through portion 20A of the resin portion 20 is cut from the side of the internal trench Ta along the trench Tb and the internal trench Ta to form the plurality of wiring structures 10 on the carrier substrate 62. The formed wiring structures 10 can be delaminated from the carrier substrate 62 and mounted on an organic wiring substrate.

### Reference Signs List

1 base material
3 insulating resin layer
5 wiring
3a, 3b, 3c pattern layer
4 relay wiring portion
5a, 5b, 5c conductor layer
7, 7B wiring layer
7A internal wiring layer
10 wiring structure (semiconductor package)
10A intermediate structure
20 resin portion
20A through portion
30 resin layer
35 opening for wiring
37 opening for trench
51 via portion
52 wiring pattern portion
71, 72 semiconductor component
80 organic wiring substrate
100 electronic component device
S1 first main surface of base material
S2 second main surface of base material
T, Tb trench
Ta internal trench

1. A method for manufacturing an electronic component device, comprising:
preparing an intermediate structure comprising a base material and a wiring layer, the base material having a first main surface and a second main surface on a rear side of the first main surface, the wiring layer being provided on the first main surface and comprising an insulating resin layer and wiring provided in the insulating resin layer, the base material comprising a resin portion comprising a through portion penetrating from the first main surface to the second main surface, the wiring layer forming a trench having a bottom surface on which the through portion is exposed; and
cutting the through portion along the trench, thereby forming a plurality of wiring structures, each comprising the divided base material and the wiring layer provided on the base material.

2. The method according to claim 1, wherein
the resin portion comprises an inorganic filler,
the insulating resin layer does not comprise an inorganic filler, or the insulating resin layer comprises the inorganic filler, and
in a case where the insulating resin layer comprises the inorganic filler, a ratio of a volume of the inorganic filler comprised in the insulating resin layer to a volume of the insulating resin layer is smaller than a ratio of a volume of the inorganic filler comprised in the resin portion to a volume of the resin portion.

3. The method according to claim 1, wherein the intermediate structure is prepared in a way that includes forming the wiring layer forming the trench on the base material.

4. The method according to claim 1, wherein the intermediate structure is prepared in a way that includes forming the wiring layer forming the trench on a carrier substrate, and shifting the wiring layer from the carrier substrate onto the base material.

5. The method according to claim 1, further comprising:
repeating a process of forming a pattern layer through exposure and development of a photosensitive resin layer to form a plurality of pattern layers, each of the pattern layers having a pattern including an opening for the wiring and an opening for the trench, the plurality of the pattern layers forming a plurality of openings for the trench; and
repeating a process of forming a conductor layer comprising a via portion that fills the opening for the wiring to form a plurality of conductor layers, wherein
the insulating resin layer of the wiring layer is formed by the plurality of the pattern layers,
the wiring of the wiring layer is formed by the plurality of the conductor layers, and
the trench is formed by connecting the plurality of the openings for the trench.

6. The method according to claim 1, further comprising:
repeating a process of forming a pattern layer by removing a part of a resin layer with laser irradiation to form a plurality of pattern layers, each of the pattern layers having a pattern including an opening for the wiring and an opening for the trench, the plurality of the pattern layers forming a plurality of openings for the trench; and
repeating a process of forming a conductor layer comprising a via portion that fills the opening for the wiring to form a plurality of conductor layers, wherein
the insulating resin layer of the wiring layer is formed by the plurality of the pattern layers,
the wiring of the wiring layer is formed by the plurality of the conductor layers, and
the trench is formed by connecting the plurality of the openings for the trench.

7. The method according to claim 1, further comprising:
repeating a process of forming a pattern layer through exposure and development of a photosensitive resin layer to form a plurality of pattern layers, each of the pattern layers having a pattern including an opening for the wiring; and
repeating a process of forming a conductor layer comprising a via portion that fills the opening for the wiring to form a plurality of conductor layers, wherein
the insulating resin layer of the wiring layer is formed by the plurality of the pattern layers,
the wiring of the wiring layer is formed by the plurality of the conductor layers, and
a part of the formed insulating resin layer is removed with laser irradiation to form the trench.

8. The method according to claim 1, further comprising mounting a plurality of semiconductor components on the wiring layer,
wherein each of the plurality of wiring structures being formed has one or more of the semiconductor components.

9. The method according to claim 1, wherein
the base material further comprises an internal wiring layer exposed on the second main surface,
the internal wiring layer forms an internal trench filled with the through portion of the resin portion,
the method further comprises mounting a plurality of semiconductor components on the internal wiring layer,
the through portion is cut along the trench and the internal trench, and
each of the plurality of wiring structures being formed comprises one or more of the semiconductor components.

10. The method according to claim 8, wherein
the base material further comprises a relay wiring portion comprising relay wiring electrically connected to the plurality of semiconductor components, the relay wiring portion being sealed by the resin portion, and
each of the plurality of wiring structures being formed comprises the relay wiring portion and two or more of the semiconductor components electrically connected via the relay wiring portion.

11. The method according to claim 1, wherein the trench has a width increasing in a direction away from the base material.

12. The method according to claim 1, further comprising mounting the wiring structure on an organic wiring substrate.
